(19) United States
(12) Patent Application Publication
(10) Pub. No.: US 2010/0001681 A1
(43) Pub. Date: Jan. 7, 2010

(54) SOLAR-POWERED DEVICE

(75) Inventors: Yazhao Zhang, Shenzhen (CN); Wu Yang, Shenzhen (CN); Dahong Zhou, Shenzhen (CN); Haitao Wang, Shenzhen (CN)

Correspondence Address: GREENBERG TRAURIG, LLP (SV);IP DOCKETING, 2450 COLORADO AVENUE, SUITE 400E, SANTA MONICA, CA, 90404, US

(73) Assignee: BYD Company Limited, Shenzhen (CN)

(21) Appl. No.: 12/423,161

(22) Filed: Apr. 14, 2009

(30) Foreign Application Priority Data
Jul. 1, 2008 (CN) 200820095158.1

(51) Int. Cl. H01M 10/46; H01L 31/048

(52) U.S. Cl. 320/101; 136/251

(57) ABSTRACT

Solar-powered device having a body for housing at least one energy storage module and at least one control module are disclosed. The body includes an opening formed by at least two recesses disposed about an upper surface of the body. At least one solar panel may be coupled to the upper surface of the body where the solar panel may be received by the recesses.

### CROSS-REFERENCE TO RELATED APPLICATION

This application claims priority to Chinese Patent Application No. 200820095158.1, filed Jul. 1, 2008.

### BACKGROUND

In modern society, oil and coal are the main energy resources. However, these non-renewable resources are gradually decreasing and as a result, the prices of oil and coal are steadily increasing. In addition, burning oil and coal is not environmental friendly. Renewable energy resources including the likes of wind, water and solar may be considered as alternatives to oil and coal.

### SUMMARY

Solar-powered devices are disclosed. In one embodiment, a device includes a body having an opening formed by at least two recesses disposed about an upper surface of the body. In one embodiment, at least one energy storage module may be housed within the body. In one embodiment, at least one control module may be housed within the body. In one embodiment, at least one solar panel may be coupled to the upper surface of the body, the solar panel being received by the recesses.

In one embodiment, the device includes a sealing component for securing the solar panel to the upper surface of the body. The sealing component may be received by the solar panel within the recesses. In one embodiment, the sealing component is an adhesive. In one embodiment, the energy storage module is a lithium-ion battery. In one embodiment, the shape of the lithium-ion battery is substantially rectangular and flat.

In one embodiment, the solar panel includes a substrate, a plurality of cells disposed about the substrate, and a transparent layer disposed about the cells. The cells may be selected from at least one of single crystal silicon, polysilicon and amorphous silicon. In some embodiments, the solar panel includes at least one of heat dissipation layer and heat dissipation component.

In one embodiment, the shape of the body may be selected from the group consisting of triangle, square, rectangle, parallelogram, pentagon and hexagon. In one embodiment, the body includes an output, where a first end of the output is coupled to at least one load and a second end of the output is coupled to the control module. In one embodiment, the control module is coupled to the energy storage module.

In one embodiment, the control module is an integrated circuit having battery charging and discharging protection modules, a solar panel charging control module, a current sharing module, a maximum power tracking module, and a constant current and constant voltage control module.

In one embodiment, the top of the upper surface of the solar panel is substantially at level with the top of the upper surface of the body. In one embodiment, the top of the upper surface of the solar panel is higher than the top of the upper surface of the body. In one embodiment, the body and the solar panel each includes at least one mounting hole, whereby the solar panel may be coupled to the upper surface of the body using at least one set screw through the mounting hole.

Other variations, embodiments and features of the presently disclosed solar-powered device will become evident from the following detailed description, drawings and claims.

### BRIEF DESCRIPTION OF THE DRAWINGS

FIGS. 1-3 are perspective, top and cross-section views, respectively, of a solar-powered device according to one embodiment of the present disclosure;

FIG. 4 is block diagram of components for the solar-powered device according to one embodiment of the present disclosure; and

FIG. 5 is block diagram of components of the solar-powered device according to one embodiment of the present disclosure.

### DETAILED DESCRIPTION

It will be appreciated by those of ordinary skill in the art that the solar-powered device can be embodied in other specific forms without departing from the spirit or essential character thereof. The presently disclosed embodiments are therefore considered in all respects to be illustrative and not restrictive.

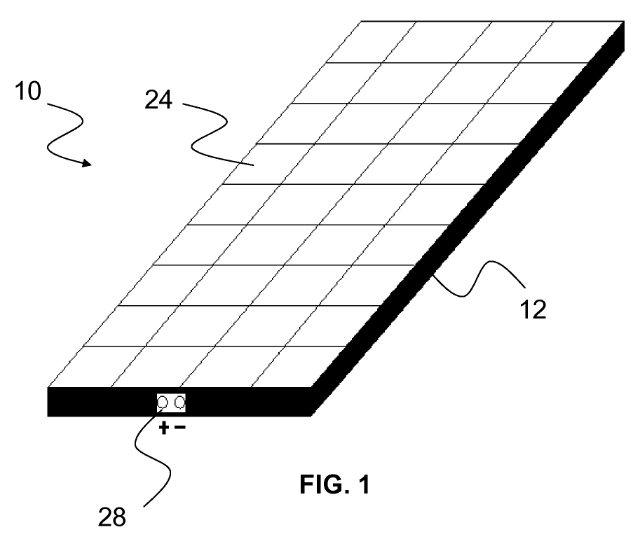

FIGS. 1-3 are perspective, top and cross-section views, respectively, of a solar-powered device 10 according to one embodiment of the present disclosure. In one embodiment, the solar-powered device 10 includes a body 12 having an opening 14. The opening 14 may be formed by at least two recesses 16 disposed about an upper surface 18 of the body 12. In one embodiment, at least one energy storage module 20 may be housed within the body 12. In one embodiment, at least one control module 22 may be housed within the body 12. In one embodiment, at least one solar panel 24 may be coupled to the upper surface 18 of the body 12. In one example, the solar panel 24 may be received by the recesses 16. In some embodiments, although two recesses 16 are shown, the solar panel 24 may be received by only a single recess 16. In one embodiment, the solar panel 24 may be received by three or more recesses 16.

In one embodiment, the energy storage module 20 and the control module 22 may be housed within the body 12. As best shown in FIG. 3, the energy storage module 20 and the control module 22 may be received within a cavity of the body 12. The solar panel 24 may be secured to the body 12 to form a sealed solar-powered device 10. In one embodiment, a sealing component 26 may be used for securing the solar panel 24 to the upper surface 18 of the body 12. In one example, the sealing component 26 may be used to couple the solar panel 24 to the recesses 16 (as best illustrated in FIG. 3). In one embodiment, the sealing component 26 is an adhesive. As shown in FIG. 3, the size of the solar panel 24 may correspond substantially with the opening 14 of the body 12.

In some embodiments, the shape of the body 12 may be selected from the group consisting of triangle, square, rectangle, parallelogram, pentagon and hexagon. In one embodiment, the shape of the solar panel 24 may be designed to correspond substantially with the shape of the body 12. In some embodiments, the shape of the solar panel 24 may be selected from the group consisting of triangle, square, rectangle, parallelogram, pentagon and hexagon. In some embodiments, the body 12 and the solar panel 24 may be designed to different shapes according to different requirements. As shown in FIG. 1, the solar-powered device 10 has a substantially flat, rectangular body 12 having a lower surface surrounded by four sidewalls and an opening 14 at the upper surface 18. Likewise, the solar panel 24 coupled to the body 12 of the solar-powered device 10 may also have a substantially flat, rectangular shape corresponding to the shapes of the opening 14 and the body 12.

The solar panel 24 may be prepared by producing a substrate having a plurality of solar cells disposed about the substrate. In one embodiment, a transparent layer may be disposed about the solar cells. In some embodiments, the solar cells may be fabricated of at least one of single crystal silicon, polysilicon and amorphous silicon. The solar cells may be connected in series or in parallel depending on voltage and current requirements. In some embodiments, the solar panel 24 may include at least one of heat dissipation layer and heat dissipation component to minimize overheating of the solar panel 24. In some instances, the solar panel 24 may also be known as a solar panel component. The solar panel 24 may also be prepared by other methods known in the art and will not be described in further detail.

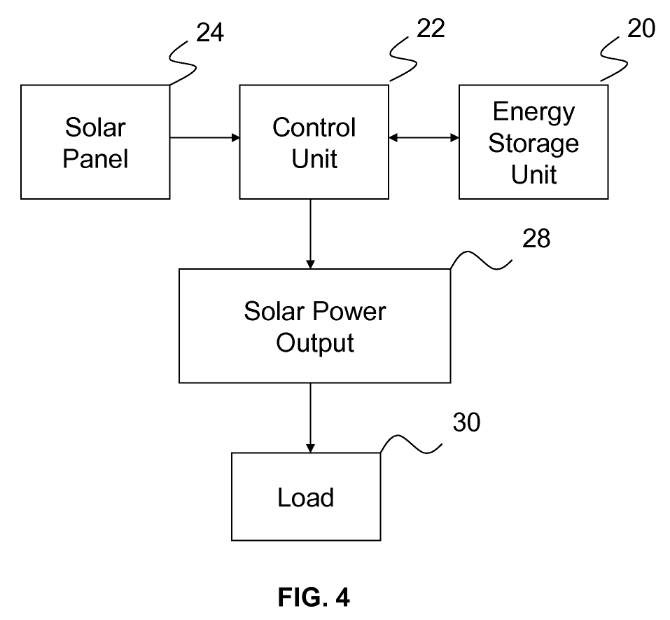

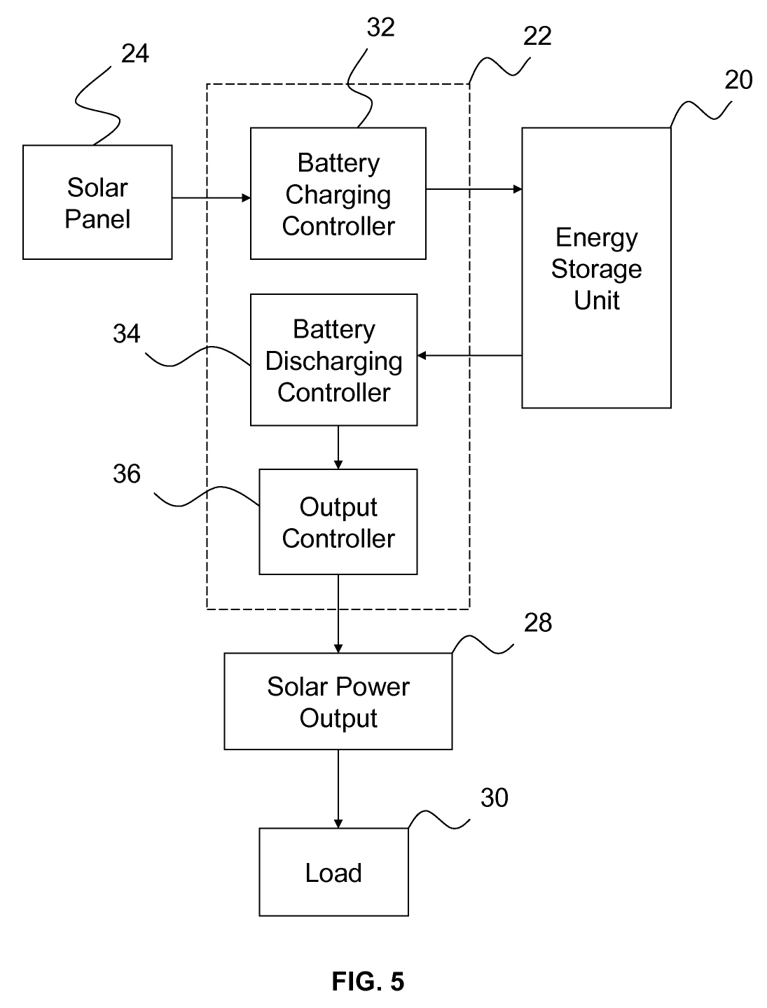

In one embodiment, the solar panel 24 includes a solar power output 28. In some embodiments, a first end of the output 28 may be coupled to at least one load 30 (best illustrated in FIGS. 4-5). The solar power output 28 is able to supply the load 30 with voltage, current and power. In one embodiment, the solar power output 28 includes positive and negative electrodes extending from a portion of the body 12 (best shown in FIG. 1). In some embodiments, a second end of the output 28 may be coupled to the control module 22, and the control module 22 may be coupled to the energy storage module 20. In one example, the energy storage module 20 is a lithium-ion battery. In one embodiment, the shape of the lithium-ion battery may be substantially rectangular and flat. In some embodiments, the shape of the lithium-ion battery may take on other polygonal shapes including square and circle, among others.

As discussed above and in one embodiment, the solar-powered device 10 may supply electricity to at least one load 30 (best illustrated in FIGS. 4-5). The types of load 30 may include street lamps and backup power supply, for example. In one example, a single 90 W, 18 V solar panel 24 may be produced. The single solar panel 24 may have a length of about 1170 mm, a width of about 530 mm, and a height of about 5 mm. The single solar panel 24 may be fabricated on about 5 inches (125 mm×125 mm) of single crystal silicon having a transforming efficiency of about 16% with lateral and longitudinal spacing of about 3 mm. In one embodiment, the solar panel 24 may have a voltage output of about 18 V and a current output of about 4.7 A. In one example, the body 12 of the solar-powered device 10 may have a length of about 1200 mm, a width of about 560 mm, a height of about 25 mm, and wall thicknesses of about 3 mm.

In some embodiments, to attach the solar-powered device 10 to a required position (e.g., solar street lamp), the device 10 may be coupled to a bracket or housing (not shown) adjacent the street lamp. In this instance, at least one mounting hole (not shown) may be disposed about the body 12 such that the solar-powered device 10 can be fixed onto the bracket or housing via the at least one mounting hole. In some embodiments, the solar panel 24 may be fastened to the body 12 via the mounting hole using screws and other fasteners.

In one example (best illustrated in FIG. 3), at least two recesses 16 may be formed about an upper surface 18 of the body 12 forming the opening 14. The recesses 16 may have a depth of from about 3 to about 5 mm. A sealing component 26 like an adhesive may be used for securing the solar panel 24 to the opening 14 and the upper surface 18 of the body 12. In one embodiment, the solar panel 24 may be secured to the recesses 16 using the adhesive sealing component 26. In one example, the thickness of the sealing adhesive 26 is about 1 mm. The dimension of the solar panel 24 may substantially correspond to the opening 14 of the body 12 and be securely fastened to the recesses 16 using the sealing adhesive 26.

In one example, the top of the upper surface of the solar panel 24 may be substantially at level with the top of the upper surface 18 of the body 12. In other words, the solar panel 24 may be flush or parallel with the body 12 as best illustrated in FIG. 3. In one example, the top of the upper surface of the solar panel 24 may be higher than the top of the upper surface 18 of the body 12. In other words, the solar panel 24 may be slightly elevated with respect to the body 12 (not shown). In some embodiments, the elevation of the solar panel 24 may help to protect the solar-powered device 10 from environmental factors including water and hail, and improve the structure and performance of the device 10. In one embodiment, the solar panel 24 may be coupled to the upper surface 18 of the body 12 using at least one set screw (not shown). In this instance, screw holes may be formed on both the solar panel 24 and the body 12 and the coupling may be made using set screws coupled to the screw holes. In some embodiments, the solar panel 24 may be coupled to the upper surface 18 of the body 12 using other fasteners including bolt and rivets, to name a few.

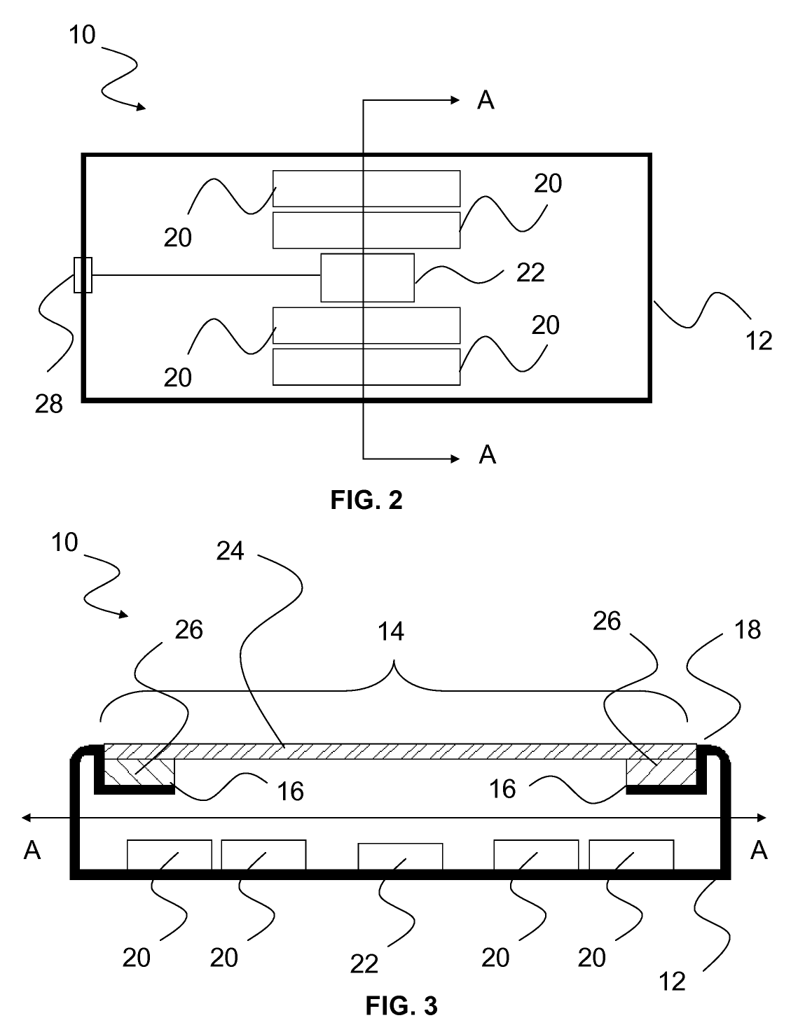

In one embodiment, the energy storage module 20 may help to store electricity converted from solar energy via the solar panel 24. In one example, the energy storage module 20 may be disposed within a cavity of the body 12. Specifically, the energy storage module 20 may be situated about the lower surface of the body 12. In one embodiment, the energy storage module 20 is a lithium-ion battery having a small volume but with high capacity. In one example, the lithium-ion battery may be a substantially flat, rectangular lithium-ion battery having a length of about 400 mm, a width of about 80 mm, and a thickness of about 15 mm. In one example, the width of the lithium-ion battery is less than the width of the body 12. In one embodiment, multiple lithium-ion batteries may be disposed about the lower surface of the body 12 as best illustrated in FIGS. 2-3. In one example, from about four to about eight lithium-ion batteries may be disposed about the lower surface of the body 12. In some embodiments, there may be more or fewer lithium-ion batteries as needed based on capacity demands and other requirements.

In one embodiment, the control module 22 may be an integrated circuit having battery charging 32 and discharging 34 protection modules (best illustrated in FIG. 5), a solar panel charging control module, a current sharing module, a maximum power tracking module, and a constant current and constant voltage control module (the remaining modules not shown).

In one embodiment, the charging 32 and discharging 34 protection modules help to minimize over charging and over discharging while the solar-powered device 10 is in operation. In some embodiments, the charging 32 and discharging 34 protection modules help to protect the energy storage module 20 among with other objects and modules within the device 10. In one example, over charging means that while the solar-powered device 10 is charging, the energy storage module 20 will not exceed a predetermined upper limit range. In one example, over discharging means that while the solar-powered device 10 is charging, the energy storage module 20 will not exceed a predetermined lower limit range. In some instances, the charging protection module 32 may be referred to as a charging controller and the discharging protection module 34 may be referred to as a discharging controller.

In one embodiment, the solar panel charging control module helps to regulate the output voltage of the solar panel to meet charging requirements. In one embodiment, the current sharing module helps to regulate charging and discharging variations among various energy storage modules 20. For example, when multiple lithium-ion batteries are utilized as the energy storage modules 20, there may be variations in charging and discharging characteristics within each lithium-ion battery due to each battery's chemical properties or methods of preparation. As such, the current sharing module is able to minimize the charging and discharging variations and maintain each battery's consistency.

In one embodiment, software systems may be employed to test the output of the solar-powered device 10. In these tests, each point may be recorded based on perturbation and observation. In one embodiment, the maximum power tracking module is able to track and determine the point where maximum power may be achieved and initiate the required charges accordingly. In one embodiment, the constant current and constant voltage output control module is equivalent to having a voltage regulator and a rectifier in providing the required load current, voltage and power for the solar-powered device 10.

In addition to the battery charging 32 and discharging 34 protection modules, and the other components described above, the control module 22 may be an integrated circuit employing other electronic devices and components including without limitation, resistors and capacitors.

FIGS. 4-5 are block diagrams outlining at least one embodiment of a process flow according to the solar-powered device 10 of the present disclosure. In one embodiment, the solar-powered device 10, having matching dimensions and other physical parameters, may be coupled to a bracket (not shown) according to the methods described above. For example, the body 12 of the solar-powered device 10 may be fastened to the bracket or housing of the load 30 such as a street lamp using set screws or other suitable fasteners. In other words, to a bracket or housing mounted on the side of a street lamp and the like.

As shown in FIG. 4, electricity may be generated by the solar panels 24 by absorbing sunlight. The electricity generated may be stored within the energy storage module 20 via the control module 22. When needed, the electricity contained within the energy storage module 20 may be supplied to a load 30 via the solar power output 28 as controlled by the control module 22.

As shown in FIG. 5, the control module 22 includes a battery charging controller 32, a battery discharging controller 34, and an output controller 36, among other components as described above. As shown in the figure, energy from the solar panel 24 is able to flow through the charging controller 32 for charging the energy storage modules 20. When electricity needs to be discharged, current can flow from the energy storage module 20, through the discharging controller 34, and out to the output controller 36. The electricity can then be outputted from the solar power output 28 and energy may subsequently be supplied to at least one load 30.

In one embodiment, the solar-powered device 10 of the present disclosure may be inlayed or fitted within the opening 14 of the body 12 and secured with the sealing component 26. In one embodiment, the control module 22 may be coupled to the energy storage module 20 using electrical leads and fixed within a portion of the body 12. In one embodiment, the solar power output 28 may be coupled to the control module 22 using electrical leads. As shown by the present disclosure, the electrical leads between the solar panel 24 and the control module 22 may be decreased thereby leading to a decrease in line loss and cost savings. In addition, the solar panel 24, the energy storage module 20, and the control module 22 may be substantially rectangular and flat thereby making them capable of being conveniently fixed to the body 12 of the solar-powered device 10. Although the solar-powered device has been described in detail with reference to several embodiments, additional variations and modifications exist within the scope and spirit as described and defined in the following claims.

What is claimed is:

1. A device comprising:
a body having an opening, wherein the opening is formed by at least two recesses disposed about an upper surface of the body;
at least one energy storage module housed within the body;
at least one control module housed within the body; and
at least one solar panel coupled to the upper surface of the body, wherein at least a portion of the solar panel is received by the recesses.

2. The device of claim 1, further comprising a sealing component for securing the solar panel to the upper surface of the body, wherein the sealing component is received by the solar panel within the recesses.

3. The device of claim 2, wherein the sealing component is an adhesive.

4. The device of claim 1, wherein the energy storage module is a lithium-ion battery.

5. The device of claim 4, wherein the shape of the lithium-ion battery is substantially rectangular and flat.

6. The device of claim 1, wherein the solar panel comprises:
a substrate;
a plurality of cells disposed about the substrate; and
a transparent layer disposed about the cells.

7. The device of claim 6, wherein the cells are selected from at least one of single crystal silicon, polysilicon and amorphous silicon.

8. The device of claim 6, wherein the solar panel further comprises at least one of heat dissipation layer and heat dissipation component.

9. The device of claim 1, wherein the shape of the body is selected from the group consisting of triangle, square, rectangle, parallelogram, pentagon and hexagon.

10. The device of claim 1, wherein the body includes an output, wherein a first end of the output is coupled to at least one load and wherein a second end of the output is coupled to the control module.

11. The device of claim 1, wherein the control module is coupled to the energy storage module.

12. The device of claim 1, wherein the control module is an integrated circuit comprising:
battery charging and discharging protection modules;
a solar panel charging control module;
a current sharing module;
a maximum power tracking module; and
a constant current and constant voltage control module.

13. The device of claim 1, wherein the top of the upper surface of the solar panel is substantially at level with the top of the upper surface of the body.

14. The device of claim 1, wherein the top of the upper surface of the solar panel is higher than the top of the upper surface of the body.

15. The device of claim 1, wherein the body and the solar panel each includes at least one mounting hole, wherein the solar panel is coupled to the upper surface of the body using at least one set screw through the mounting hole.

16. A device comprising:
a body having an opening, wherein the opening is formed by at least two recesses disposed about an upper surface of the body;
at least one energy storage module housed within the body;
at least one control module housed within the body; and
at least one solar panel coupled to the upper surface of the body, wherein at least a portion of the solar panel is received by the recesses using a sealing component, and wherein the sealing component comprises an adhesive, and wherein the top of the upper surface of the solar panel is substantially at level with the top of the upper surface of the body.

17. The device of claim 16, wherein the energy storage module is a lithium-ion battery.

18. A device comprising:
a body having an opening, wherein the opening is formed by at least two recesses disposed about an upper surface of the body;
at least one energy storage module housed within the body;
at least one control module housed within the body, wherein the control module is an integrated circuit comprising:
battery charging and discharging protection modules;
a solar panel charging control module;
a current sharing module;
a maximum power tracking module;
a constant current and constant voltage control module;
at least one solar panel coupled to the upper surface of the body, wherein the solar panel comprises:
a substrate;
a plurality of cells disposed about the substrate;
a transparent layer disposed about the cells; and
wherein the body includes an output, wherein a first end of the output is coupled to at least one load, wherein a second end of the output is coupled to the control module, wherein the control module is coupled to the energy storage module, wherein at least a portion of the solar panel is received by the recesses using a sealing component, and wherein the sealing component comprises an adhesive, and wherein the top of the upper surface of the solar panel is substantially at level with the top of the upper surface of the body.

19. The device of claim 18, wherein the energy storage module is a lithium-ion battery.
